(19) United States
(12) Patent Application Publication
(10) Pub. No.: US 2016/0349586 A1
(43) Pub. Date: Dec. 1, 2016

(54) Array Substrate and Manufacturing Method thereof and Liquid Crystal Display

(71) Applicant: SHENZHEN CHINA STAR OPTOELECTRONICS TECHNOLOGY CO., LTD., Shenzhen City, Guangdong (CN)

(72) Inventor: Hua ZHENG, Shenzhen, Guangdong (CN)

(73) Assignee: Shenzhen China Star Optoelectronics Technology Co., Ltd., Shenzhen, Guangdong (CN)

(21) Appl. No.: 14/426,205

(22) PCT Filed: Dec. 29, 2014
(86) PCT No.: PCT/CN2014/095314

§ 371 Date: Mar. 5, 2015

(30) Foreign Application Priority Data
Nov. 26, 2014 (CN) 201410692999.0

(51) Int. Cl. G02F 1/1362; G02F 1/1368; H01L 27/12; G02F 1/1343

(52) U.S. Cl. CPC G02F 1/136286; G02F 1/134309; G02F 1/1368; G02F 1/136227; H01L 27/124; G02F 2201/121; G02F 2201/123

(57) ABSTRACT

The present invention disclosures an array substrate and a manufacturing method thereof and a liquid crystal display, which comprise: a substrate; a plurality of data lines which is disposed on the substrate; a plurality of scan lines which is intersected the data lines; a plurality of common electrode lines which are intersected the data lines; each two adjacent scan lines and two adjacent data lines define a pixel structure, it comprises: a thin film transistor component which is electrically connected with the data lines and the scan lines; a first pixel electrode, a second pixel electrode, a third pixel electrode and a fourth pixel electrode, forming 2×2 structure, electrically connecting with the thin film transistor component, to be spaced apart through the common electrode lines, wherein the common electrode lines of the first pixel electrode, the second pixel electrode, the third pixel electrode and the fourth pixel electrode are connected together. Through the above way, the present invention can make the common electrode form a close network with low resistance, excellently stabilizing the voltage of the common electrode line, avoiding the bad display caused by inaccuracy of the pixel charge.

### BACKGROUND OF THE INVENTION

1. Field of the Invention

The present invention relates to a display technical field, and in particular to an array substrate and a manufacturing method thereof and a liquid crystal display.

2. The Related Arts

FIG. 1 illustrates a liquid crystal panel pixel with five mask process in detail. Wherein the thin black line frames a size of pixel 100. The pixel 100 comprises: first metal layers 11, 13 which are used to produce a scan line 11 and a common electrode 13; an amorphous silicon layer 14 which is used for the production of the active layer of TFT (Thin Film Transistor); a via layer 16 which are used to produce vias in order to make the metals of top layer and bottom layer conducted; a pixel electrode layer 15 which is used to produce a pixel electrode ITO region.

In the common panel design, the pixel is arranged simply and repeatability. Therefore, the pixel array as shown in FIG. 1 can be turned into the structure as shown in FIG. 2. As shown in FIG. 2, because the common electrode line 13 and the scan line 11 are the same layer metal equipment, and the common electrode lines 13 of each row pixel are not in contact in the column array, only can be contacted through the special trace outside the array. Considering the aperture ratio, the common electrode lines 13 are commonly narrow, cannot connect with the common electrode that is in different row through additional vias. Moreover, the RC delay of the common electrode line 13 in the array is great, the potential of the common electrode line 13 is easily affected by the data line 11 and the pixel electrode layer 15 during charging process, resulting the charge voltage of the pixel electrode ITO is inaccurate.

### SUMMARY OF THE INVENTION

The technical issues solved by the present invention are to provide an array substrate and a manufacturing method thereof and a liquid crystal display, making the common electrode form a close network with low resistance, excellently stabilizing the voltage of the common electrode line, avoiding the bad display caused by inaccuracy of the pixel charge.

In order to solve the above technical issues, the present invention provides an array substrate which comprises:

a substrate;

a plurality of data lines which is disposed on the substrate;

a plurality of scan lines which is intersected the data lines;

a plurality of common electrode lines which are intersected the data lines;

each two adjacent scan lines and two adjacent data lines define a pixel structure, it comprises:

a thin film transistor component which is electrically connected with the data lines and the scan lines;

a first pixel electrode, a second pixel electrode, a third pixel electrode and a fourth pixel electrode, forming 2×2 structure, electrically connecting with the thin film transistor component, to be spaced apart through the common electrode lines, wherein the common electrode lines of the first pixel electrode, the second pixel electrode, the third pixel electrode and the fourth pixel electrode are connected together.

Wherein the pixel structure is central symmetry.

Wherein the common electrode line in the middle of the pixel structure is cruciform.

Wherein both ends of the electrode line close to the scan line are provided vias.

Wherein the via is connected with the common electrode line of the adjacent pixel structure through the metal trace.

In order to solve the above technical issues, the present invention provides a manufacturing method of an array substrate, it comprises: define a pixel structure from the two adjacent scan lines and the two adjacent data lines on the substrate, the pixel structure comprises: a thin film transistor component which is electrically connected with the data lines and the scan lines; a first pixel electrode, a second pixel electrode, a third pixel electrode and a fourth pixel electrode, forming 2×2 structure, electrically connecting with the thin film transistor component, to be spaced apart through the common electrode lines; connect together the common electrode lines of the first pixel electrode the second pixel electrode, the third pixel electrode and the fourth pixel electrode.

Wherein the pixel structure is central symmetry.

Wherein the common electrode line in the middle of the pixel structure is cruciform.

Wherein both ends of the electrode line close to the scan line are provided vias, the vias are connected with the common electrode line of the adjacent pixel structure through the metal trace.

In order to solve the above technical issues, the present invention provides a liquid crystal display, it comprises an array substrate which comprises:

a substrate;

a plurality of data lines which is disposed on the substrate;

a plurality of scan lines which is intersected the data lines;

a plurality of common electrode lines which are intersected the data lines;

each two adjacent scan lines and two adjacent data lines define a pixel structure, it comprises:

a thin film transistor component which is electrically connected with the data lines and the scan lines;

a first pixel electrode, a second pixel electrode, a third pixel electrode and a fourth pixel electrode, forming 2×2 structure, electrically connecting with the thin film transistor component, to be spaced apart through the common electrode lines, wherein the common electrode lines of the first pixel electrode, the second pixel electrode, the third pixel electrode and the fourth pixel electrode are connected together.

Wherein the pixel structure is central symmetry.

Wherein the common electrode line in the middle of the pixel structure is cruciform.

Wherein both ends of the electrode line close to the scan line are provided vias.

Wherein the via is connected with the common electrode line of the adjacent pixel structure through the metal trace.

Through the above solutions, the benefits of the present invention are: through each two adjacent scan lines and two adjacent data lines define a pixel structure which comprises: a thin film transistor component which is electrically connected with the data lines and the scan lines; a first pixel electrode, a second pixel electrode, a third pixel electrode and a fourth pixel electrode, forming 2×2 structure, electrically connecting with the thin film transistor component, to be spaced apart through the common electrode lines; wherein the common electrode lines of the first pixel electrode, the second pixel electrode, the third pixel electrode and the fourth pixel electrode are connected together, making the common electrode form a close network with low resistance, excellently stabilizing the voltage of the common electrode line, avoiding the bad display caused by inaccuracy of the pixel charge.

### BRIEF DESCRIPTION OF THE DRAWINGS

FIG. 1 is a schematic diagram of a pixel structure in the prior art;

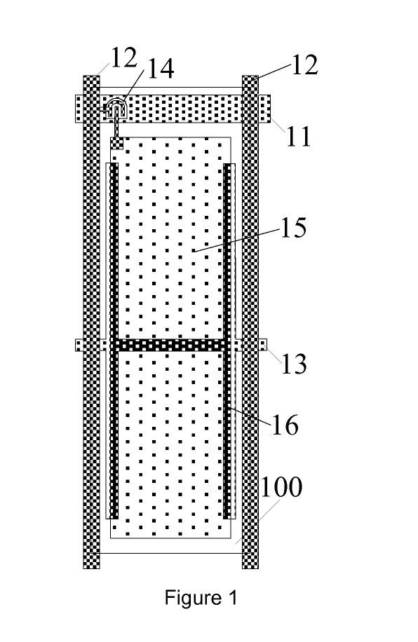

FIG. 2 is a structure diagram of an array substrate in the prior art;

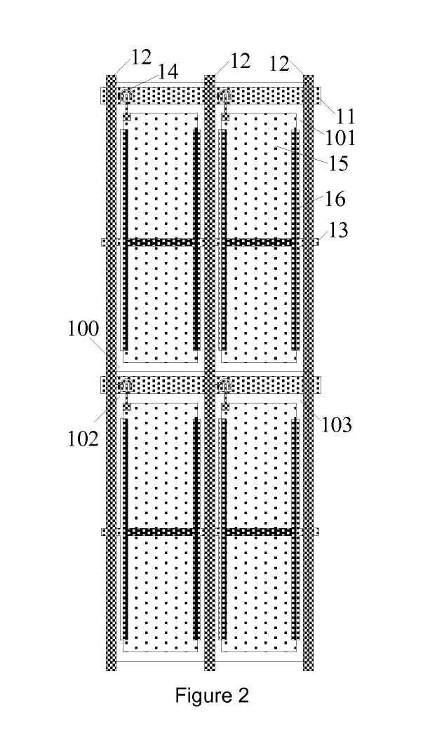

FIG. 3 is a structure diagram of an array substrate in the embodiment of the present invention;

FIG. 4 is a arrangement schematic diagram of a pixel of an array substrate in the embodiment of the present invention;

FIG. 5 is a flow schematic diagram of a manufacturing method of an array substrate in the embodiment of the present invention.

### DETAILED DESCRIPTION OF THE PREFERRED EMBODIMENTS

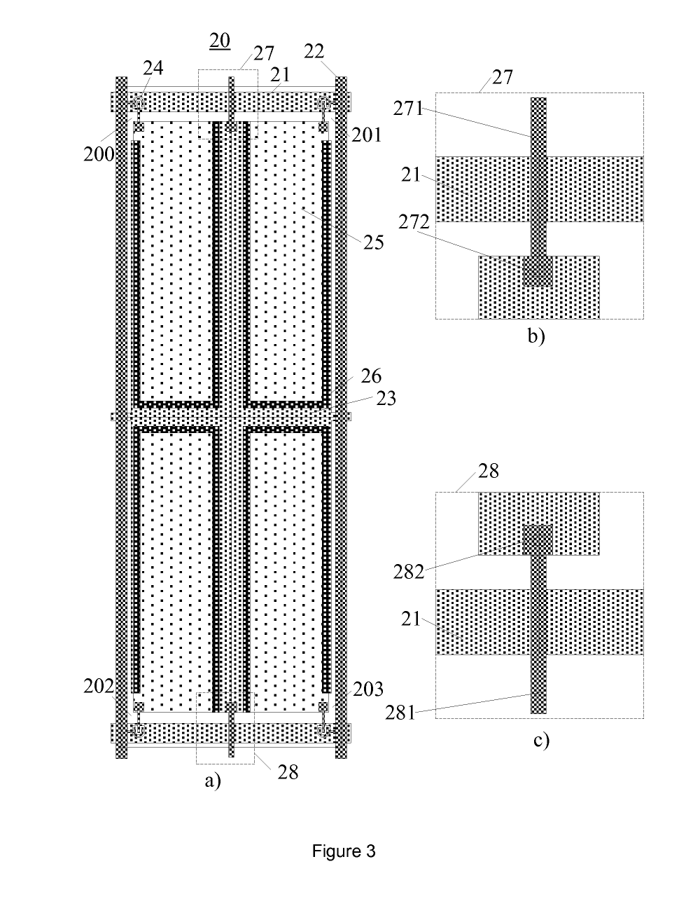

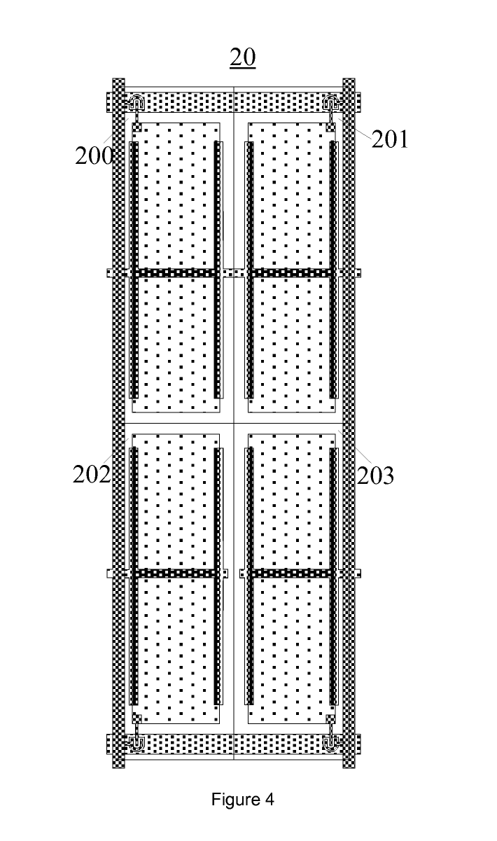

Refer to FIG. 3, FIG. 3 is a structure diagram of an array substrate in the embodiment of the present invention. As shown in Figure a of FIG. 3, the array substrate comprises a substrate (not shown in figure), a plurality of data lines 22, a plurality of scan lines 21 and a plurality of common electrode lines 23. The plurality of data lines 22 are disposed on the substrate, the plurality of scan lines 21 intersect the data lines 22, the plurality of common electrode lines 23 are intersected on the data lines 22. Each two adjacent scan lines 21 and two adjacent data lines 22 define a pixel structure 200. The pixel structure 200 comprises: a thin film transistor component 24, a first pixel electrode 200, a second pixel electrode 201, a third pixel electrode 202 and a fourth pixel electrode 203. The thin film transistor component 24 is electrically connected with the data line 22 and the scan line 21; the first pixel electrode 200, the second pixel electrode 201, the third pixel electrode 202 and the fourth pixel electrode 203 form 2×2 structure, electrically connecting with the thin film transistor component, to be spaced apart through the common electrode lines. Wherein the common electrode lines of the first pixel electrode 200, the second pixel electrode 201, the third pixel electrode 202 and the fourth pixel electrode 203 are connected together. The common electrode line 23 in the middle of the pixel structure 20 is cruciform, the width is 5-20 um, the space is big enough to produce the via 272 to connect with the common electrode line. In FIG. 3, figure b is a structure diagram of an enlarged dotted frame 27, figure c is a structure diagram of an enlarged dotted frame 27. Both ends of the common electrode line 23 near the scan line 21 are provided the vias 272, 282. The vias 272, 282 are connected with the common electrode line of the adjacent pixel structure through the metal traces 271, 281. It can be seen in figure a of FIG. 3, the pixel structure 20 is central symmetry. The forming process as shown in FIG. 4, every 2×2 adjacent pixels 200, 201, 202, 203 composes a pixel structure 20, rearranging through adopting center-symmetrical layout, the common electrode line between the pixel 200 and the pixel 201, the common electrode line between the pixel 200 and the pixel 202, and the common electrode line between the pixel 201 and the pixel 203 will no longer be spaced apart by the scan line, thus those can be connected together, forming the cruciform common electrode line as shown in FIG. 3, the width also increases, in order to respectively produce vias on the upper end and the lower end near the scan line, respectively connecting with the common electrode line of the pixel structure adjacent to upper and down through the vias, making the common electrode form a close network with low resistance, greatly reducing the resistance of the common electrode line, the unitary common electrode line potential fluctuations can be quickly balanced out, avoiding the bad display caused by inaccuracy of the pixel charge.

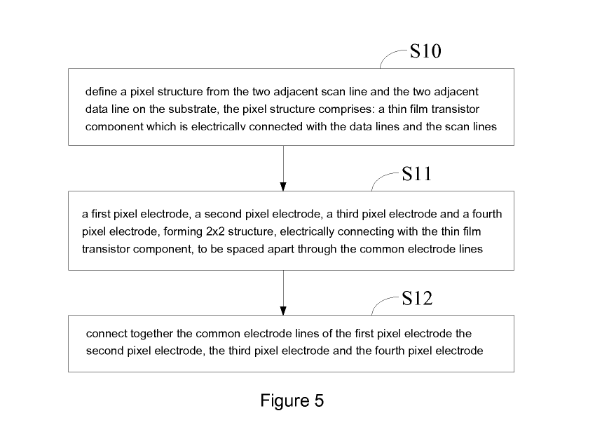

FIG. 5 is a flow schematic diagram of a manufacturing method of an array substrate in the embodiment of the present invention. As shown in FIG. 5, the manufacturing method of the array substrate comprises:

Step S10: define a pixel structure from the two adjacent scan lines and the two adjacent data lines on the substrate, the pixel structure comprises: a thin film transistor component which is electrically connected with the data lines and the scan lines.

The array substrate comprises a substrate, a plurality of data lines, a plurality of scan lines and a plurality of common electrode lines. The plurality of data lines 22 are disposed on the substrate, the plurality of scan lines intersect the data lines, the plurality of common electrode lines are intersected on the data lines. The pixel structure in step S10 is central symmetry. The thin film transistor component is located on the junction between the scan line and the data line; namely, it is four corners of the pixel structure.

Step S11: a first pixel electrode, a second pixel electrode, a third pixel electrode and a fourth pixel electrode, forming 2×2 structure, electrically connecting with the thin film transistor component, to be spaced apart through the common electrode lines. Thus the common electrode line between two adjacent pixel electrode is no longer spaced apart by the scan line, making the adjacent common electrode line connected.

Step S12: connect together the common electrode lines of the first pixel electrode the second pixel electrode, the third pixel electrode and the fourth pixel electrode.

In step S12, connect the common electrode line between two adjacent pixel electrodes, thus the common electrode line in the middle of the pixel structure is cruciform, the width of the common electrode line also increases. Both ends of the electrode line close to the scan line are provided vias, which are connected with the common electrode line of the adjacent pixel structure through the metal trace, making the common electrode form a close network with low resistance, greatly reducing the resistance of the common electrode line, the unitary common electrode line potential fluctuations can be quickly balanced out, avoiding the bad display caused by inaccuracy of the pixel charge.

The embodiment of the present invention also provides a liquid crystal display, it comprises an array substrate as shown in FIG. 3.

The present invention define a pixel structure through each two adjacent scan lines and two adjacent data lines, the pixel structure comprises: a thin film transistor component which is electrically connected with the data lines and the scan lines; a first pixel electrode, a second pixel electrode, a third pixel electrode and a fourth pixel electrode, forming 2×2 structure, electrically connecting with the thin film transistor component, to be spaced apart through the common electrode lines; wherein the common electrode lines of the first pixel electrode, the second pixel electrode, the third pixel electrode and the fourth pixel electrode are connected together, making the common electrode form a close network with low resistance, excellently stabilizing the voltage of the common electrode line, avoiding the bad display caused by inaccuracy of the pixel charge.

The preferred embodiments according to the present invention are mentioned above, which cannot be used to define the scope of the right of the present invention. Those variations of equivalent structure or equivalent process according to the present specification and the drawings or directly or indirectly applied in other areas of technology are considered encompassed in the scope of protection defined by the clams of the present invention.

What is claimed is:

1. An array substrate, wherein the array substrate comprises:
a substrate;
a plurality of data lines which being disposed on the substrate;
a plurality of scan lines which being intersected the data lines;
a plurality of common electrode lines which being intersected the data lines;
each two adjacent scan lines and two adjacent data lines defining a pixel structure, the pixel structure comprises:
a thin film transistor component which being electrically connected with the data lines and the scan lines;
a first pixel electrode, a second pixel electrode, a third pixel electrode and a fourth pixel electrode, forming 2×2 structure, electrically connecting with the thin film transistor component, to be spaced apart through the common electrode lines, wherein the common electrode lines of the first pixel electrode, the second pixel electrode, the third pixel electrode and the fourth pixel electrode being connected together.

2. The array substrate as Claimed in claim 1, wherein the pixel structure is central symmetry.

3. The array substrate as Claimed in claim 1, wherein the common electrode line in the middle of the pixel structure is cruciform.

4. The array substrate as Claimed in claim 1, wherein both ends of the electrode line close to the scan line are provided vias.

5. The array substrate as Claimed in claim 4, wherein the via is connected with the common electrode line of the adjacent pixel structure through a metal trace.

6. A manufacturing method of an array substrate, wherein the method comprises:
defining a pixel structure from the two adjacent scan lines and the two adjacent data lines on the substrate, the pixel structure comprises:
a thin film transistor component which being electrically connected with the data lines and the scan lines;
a first pixel electrode, a second pixel electrode, a third pixel electrode and a fourth pixel electrode, forming 2×2 structure, electrically connecting with the thin film transistor component, to be spaced apart through the common electrode lines;
connecting together the common electrode lines of the first pixel electrode the second pixel electrode, the third pixel electrode and the fourth pixel electrode.

7. The method as claimed in claim 6, wherein the pixel structure is central symmetry.

8. The method as claimed in claim 6, wherein the common electrode line in the middle of the pixel structure is cruciform.

9. The method as claimed in claim 6, wherein both ends of the electrode line close to the scan line are provided vias, which are connected with the common electrode line of the adjacent pixel structure through a metal trace.

10. A liquid crystal display, wherein it comprises an array substrate, the array substrate comprising:
a substrate;
a plurality of data lines which being disposed on the substrate;
a plurality of scan lines which being intersected the data lines;
a plurality of common electrode lines which being intersected the data lines;
each two adjacent scan lines and two adjacent data lines defining a pixel structure, it comprising:
a thin film transistor component which being electrically connected with the data lines and the scan lines;
a first pixel electrode, a second pixel electrode, a third pixel electrode and a fourth pixel electrode, forming 2×2 structure, electrically connecting with the thin film transistor component, to be spaced apart through the common electrode lines, wherein the common electrode lines of the first pixel electrode, the second pixel electrode, the third pixel electrode and the fourth pixel electrode being connected together.

11. The array substrate as Claimed in claim 10, wherein the pixel structure is central symmetry.

12. The array substrate as Claimed in claim 10, wherein the common electrode line in the middle of the pixel structure is cruciform.

13. The array substrate as Claimed in claim 10, wherein both ends of the electrode line close to the scan line are provided vias.

14. The array substrate as Claimed in claim 13, wherein the via is connected with the common electrode line of the adjacent pixel structure through the metal trace.
